(19) United States
(12) Patent Application Publication
(10) Pub. No.: US 2025/0330002 A1
(43) Pub. Date: Oct. 23, 2025

(54) ELECTRICAL JUNCTION BOX

(71) Applicant: Sumitomo Wiring Systems, Ltd., Yokkaichi-shi, Mie (JP)

(72) Inventors: Kiyofumi KAWAGUCHI, Yokkaichi-Shi, Mie (JP); Tatsuya FUJISAKA, Yokkaichi-Shi, Mie (JP)

(73) Assignee: Sumitomo Wiring Systems, Ltd., Yokkaichi-shi, Mie (JP)

(21) Appl. No.: 18/870,137

(22) PCT Filed: May 17, 2023
(86) PCT No.: PCT/JP2023/018477

§ 371 Date: Nov. 27, 2024

(30) Foreign Application Priority Data
Jun. 1, 2022 (JP) 2022-089775

(51) Int. Cl. H02G 3/08; B60R 16/023

(52) U.S. Cl. CPC H02G 3/081; B60R 16/0238; B60R 16/0239

(57) ABSTRACT

Provided is an electrical junction box that includes a fastening portion to be used for mounting the electrical junction box to a battery pack, and is to be mounted, from outer surface thereof, to the battery pack, the fastening portion is positioned in a central portion of an outer surface, and a flexure preventing mechanism for preventing flexure of the outer surface is provided in the vicinity of the fastening portion.

### CROSS-REFERENCE TO RELATED APPLICATIONS

This application is the U.S. national stage of PCT/JP2023/018477 filed on May 17, 2023, which claims priority of Japanese Patent Application No. JP 2022-089775 filed on Jun. 1, 2022, the contents of which are incorporated herein.

### TECHNICAL FIELD

The present disclosure relates to an electrical junction box.

### BACKGROUND

Heretofore, an electrical junction box that accommodates electronic components such as fuses and relays is mounted in vehicles.

The electrical junction box includes a housing, and the housing is constituted by a first case that is open on one surface side thereof and accommodates the electronic components, and a second case that covers the one surface side of the first case that is open, for example (see JP 2016-208561A).

The above electrical junction box is attached to the mount target from the bottom side of the first case. Specifically a bolt is inserted into a through hole provided in the bottom of the first case from the mount target and is threaded into the through hole. At this time, in order to prevent threaded connection from loosening due to thermal expansion of the electrical junction box, a collar is provided in the through hole, and the above threading operation is performed in a state where the collar and the mount target abut on each other.

However, when the bottom of the first case flexes downward due to the weight thereof, for example, the bottom comes into contact with the mount target before the collar, and thus, in the above threading operation, a problem occurs in that the collar and the mount target are prevented from abutting on each other.

However, as far as the electrical junction box of JP 2016-208561A is concerned, such a problem is not taken into consideration, and cannot be solved.

In view of this, an object of the present disclosure is to provide an electrical junction box that can prevent the occurrence of flexure of one surface that abuts on a mount target at the time of attachment.

### SUMMARY

An electrical junction box according to an embodiment of the present disclosure is an electrical junction box that includes a mount portion to be used for mounting the electrical junction box to a target object, and is to be mounted, from one surface thereof, to the target object, the mount portion is positioned in a central portion of the one surface, and a flexure preventing mechanism for preventing flexure of the one surface is provided in the vicinity of the mount portion.

### Advantageous Effects

According to the present disclosure, it is possible to provide an electrical junction box that can prevent the occurrence of flexure of one surface that abuts on a mount target at the time of attachment.

### BRIEF DESCRIPTION OF THE DRAWINGS

FIG. 1 is a perspective view of an electrical junction box according to an embodiment of the present disclosure.

FIG. 2A is a plan view of the electrical junction box according to the embodiment.

FIG. 2B is a side view of the electrical junction box according to the embodiment.

FIG. 3 is an exploded view of the electrical junction box according to the embodiment.

FIG. 4 is a perspective view of a bottom surface of the electrical junction box according to the embodiment.

FIG. 5 is a partial cross-sectional perspective view taken along the line A-A in FIG. 4.

FIG. 6 is a longitudinal cross-sectional view taken along the line A-A in FIG. 4.

FIG. 7 is a partial cross-sectional perspective view taken long the line B-B in FIG. 4.

### DETAILED DESCRIPTION OF PREFERRED EMBODIMENTS

First, embodiments of the present disclosure will be listed and described. In addition, at least some of the embodiments described below may be combined as appropriate.

An electrical junction box according to an embodiment of the present disclosure is an electrical junction box that includes a mount portion to be used for mounting the electrical junction box to a target object, and is to be mounted, from one surface thereof, to the target object, the mount portion is positioned in a central portion of the one surface, and a flexure preventing mechanism for preventing flexure of the one surface is provided in the vicinity of the mount portion.

According to such an embodiment, the flexure preventing mechanism for preventing flexure is provided in the vicinity of the mount portion positioned in the central portion of the one surface. Therefore, it is possible to prevent flexure of the one surface, and prevent the electrical junction box from not being appropriately mounted to the target object due to flexure of the one surface.

The electrical junction box according to the embodiment of the present disclosure includes: a first case that includes the one surface and an open portion formed on an opposing side to the one surface, and a second case that covers the open portion of the first case, and the flexure preventing mechanism includes: an engaging portion provided on the first case, and an engaged portion that is provided in the second case and is configured to be engaged with the engaging portion.

According to such an embodiment, the flexure preventing mechanism includes the engaging portion provided on the first case, and the engaged portion that is provided in the second case and is engaged with the engaging portion. Therefore, as a result of attaching the first case and the second case to each other, the engaging portion and the engaged portion are engaged with each other, and the flexure preventing mechanism prevents flexure of the one surface.

The electrical junction box according to the embodiment of the present disclosure further includes a check window that is formed in the one surface, and is for checking engagement between the engaging portion and the engaged portion.

According to such an embodiment, the check window for checking engagement between the engaging portion and the engaged portion is provided. Therefore, when the first case and the second case are attached to each other, an operator can check whether or not the engaging portion and the engaged portion are appropriately engaged with each other, through the check window.

In the electrical junction box according to the embodiment of the present disclosure, the mount portion is provided on the second case, and is fitted into a through tube formed in the one surface, the engaging portion is provided in the through tube, and the engaged portion is formed integrally with the mount portion.

According to such an embodiment, the engaging portion is provided in the through tube, and the engaged portion is formed integrally with the mount portion. Therefore, when the first case and the second case are attached to each other, the engaging portion and the engaged portion are engaged with each other simply by inserting the mount portion of the second case into the through tube of the first case.

An electrical junction box according to an embodiment of the present disclosure will be described below with reference to the drawings. Note that the present disclosure is not limited to illustrations of these, but is indicated by the claims, and is intended to include all modifications that are within the meanings and the scope that are equivalent to those of the claims.

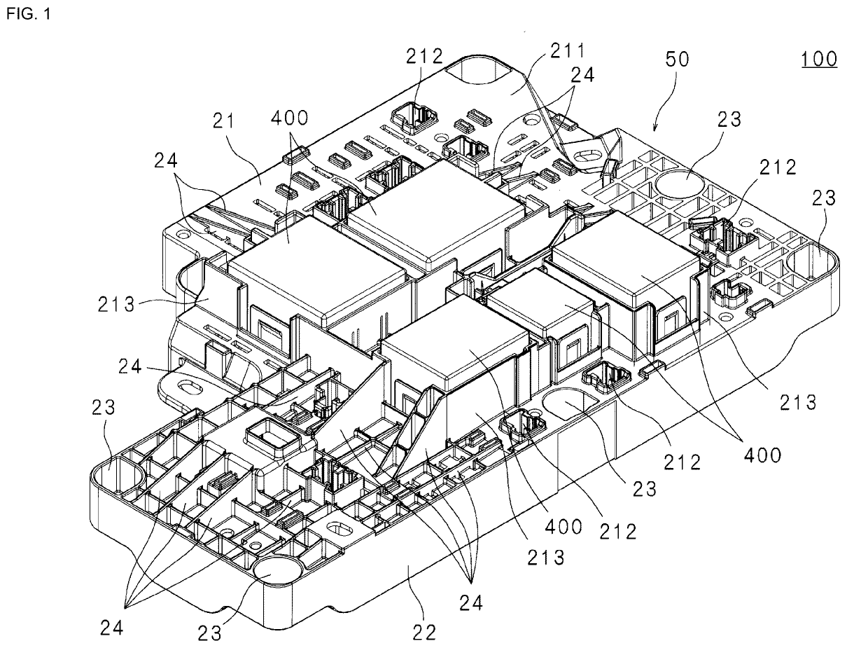

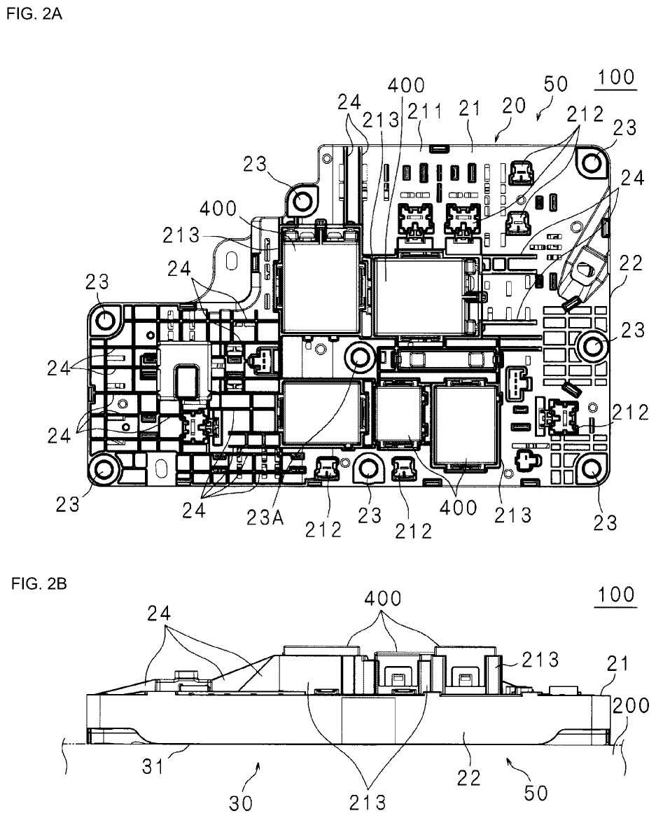

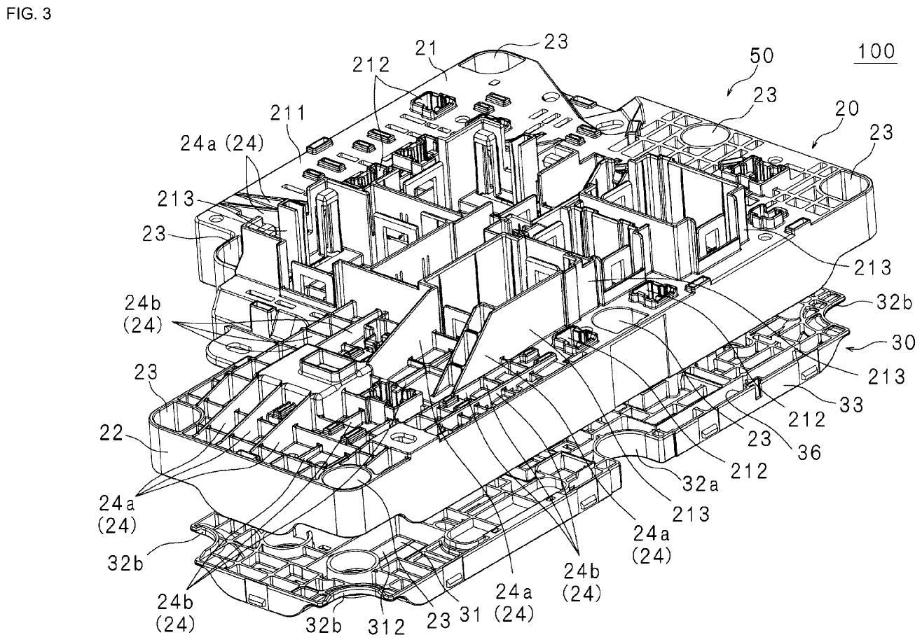

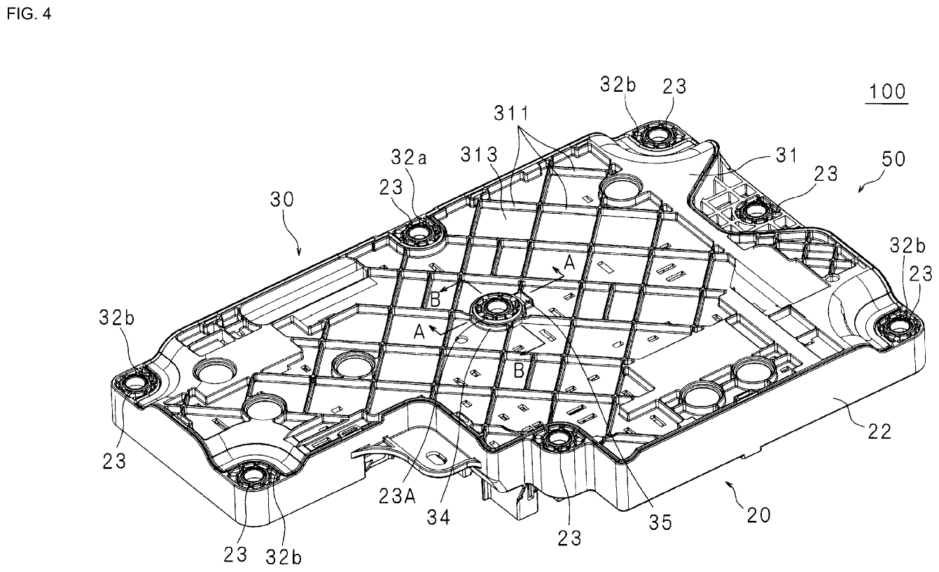

FIG. 1 is a perspective view of an electrical junction box 100 according to an embodiment of the present disclosure, FIGS. 2A and 2B are a plan view and a side view of the electrical junction box 100 according to the embodiment, FIG. 3 is an exploded view of the electrical junction box 100 according to the embodiment, and FIG. 4 is a perspective view of the bottom surface of the electrical junction box 100 according to the embodiment. FIG. 2A is a plan view of the electrical junction box 100, and FIG. 2B is a side view of the electrical junction box 100.

The electrical junction box 100 is attached to the outer side of a mount target (target object) such as a battery pack 200 (see FIG. 2) of an EV (Electric Vehicle), for example.

The electrical junction box 100 includes a housing 50 that accommodates a fuse, a board, and the like. The housing 50 is a flattened box, is substantially rectangular in plan view, and has a shape in which one corner of one end portion in the lengthwise direction is notched in a stepped manner. The housing 50 is made of a resin, for example, and is constituted by a lower case 30 (first case) that is attached to the mount target, and an upper case 20 (second case) that covers the lower case 30. For convenience of description, the following description is given in which the upper case 20 side is the upper side, and the lower case 30 side is the lower side.

The lower case 30 has a shape of a box in which one surface on the upper case 20 side is open to form an open portion 36. The lower case 30 includes a bottom wall 31 whose outer side comes into contact with the mount target, and a side wall 33 extending perpendicularly from an edge of the bottom wall 31 to the upper case 20 side. Ribs are formed at a plurality of locations inside the lower case 30 (see FIG. 3).

Recessed portions 32b are formed in the two end portions in the lengthwise direction of the bottom wall 31 of the lower case 30, and a recessed portion 32a is formed in an intermediate portion. The recessed portion 32a and the recessed portions 32b are formed at positions corresponding to fastening portions 23 (mount portions) of the upper case 20, which will be described later.

Specifically, the recessed portions 32b are respectively formed in the two corners of each of the two end portions of the lower case 30. The recessed portions 32b are substantially rectangular in plan view, the side wall 33 is bent at substantially the right angle in the recessed portions 32b, and the corners of each recess are chamfered (see FIG. 3).

In addition, the recessed portion 32a is formed in an intermediate portion on a longer edge side of the lower case 30. The recessed portion 32a is substantially rectangular in plan view. In the recessed portion 32a, the side wall 33 is recessed inward in the lower case 30, and the corners of the recess are chamfered (see FIG. 3).

Furthermore, a through tube 34 into which a later-described fastening portion 23A of the upper case 20 is inserted is formed in a substantially central portion of the bottom wall 31. The through tube 34 is cylindrical, and passes through the bottom wall 31 in the thickness direction thereof. That is to say, the axial center of the through tube 34 extends in the thickness direction of the bottom wall 31, and one side of the through tube 34 protrudes perpendicularly from an inner surface 312 of the bottom wall 31, and the other side protrudes perpendicularly from an outer surface 313 (one surface) of the bottom wall 31. The fastening portion 23A of the upper case 20 is fitted into the through tube 34, and extends beyond the lower end of the through tube 34. In addition, on the outer surface 313 of the bottom wall 31, ribs 311 are erected in a lattice shape, for example.

The upper case 20 has a shape of a box in which the one surface on the lower case 30 side is open. The lengths of the upper case 20 in the lengthwise direction and in the width direction orthogonal to the lengthwise direction are slightly larger than those of the lower case 30, and the upper case 20 covers the open portion 36 of the lower case 30.

In addition, the upper case 20 includes a ceiling wall 21 that opposes the bottom wall 31 of the lower case 30, and a side wall 22 that is disposed around an edge of the ceiling wall 21 and extends in the up-down direction. The fastening portions 23 and 23A for attaching the housing 50 (the electrical junction box 100) to the mount target are provided in the two end portions and an intermediate portion in the lengthwise direction of the upper case 20.

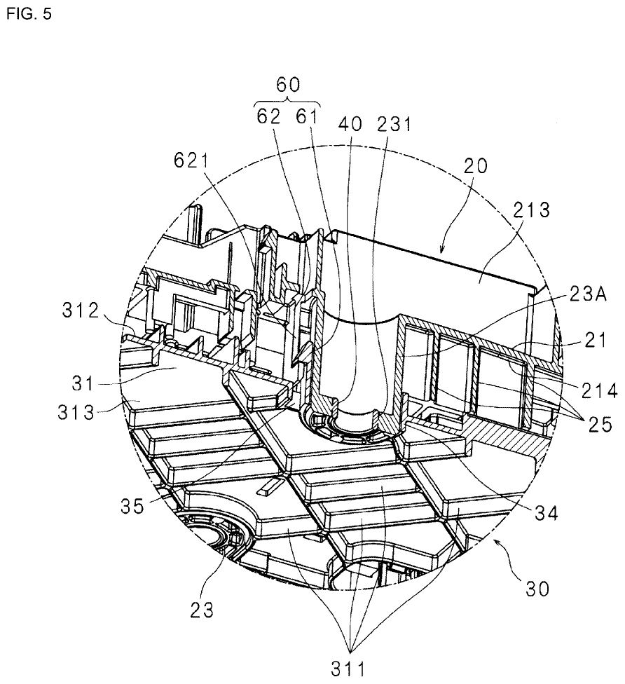

Specifically the fastening portions 23 are respectively provided at the two corners of one end portion in the lengthwise direction of the upper case 20, and are respectively provided at the two corners of the other end portion and between the two corners. Furthermore, also in the intermediate portion in the lengthwise direction of the upper case 20, three fastening portions, namely the fastening portions 23 and 23A are aligned in the width direction. The fastening portions 23 and 23A protrude from the inner surface 214 of the ceiling wall 21 that opposes the bottom wall 31 (see FIG. 5), and the fastening portions 23 other than the one fastening portion 23A in the substantially central portion of the ceiling wall 21 are provided in the vicinity of the side wall 22 (see FIG. 2A).

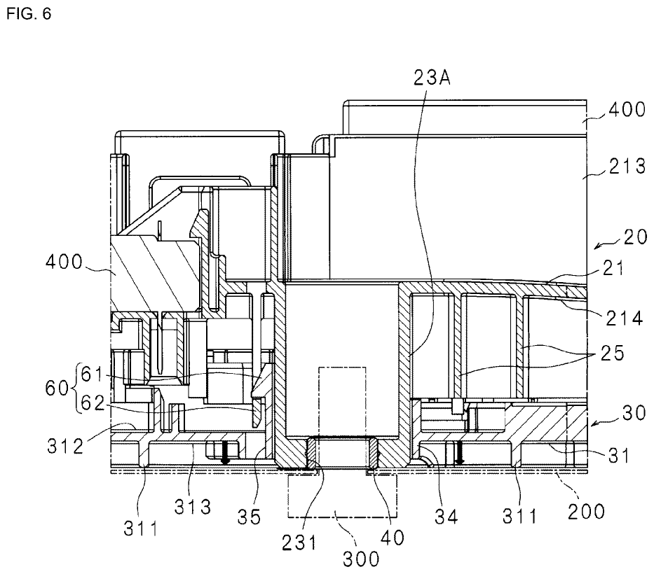

In addition, a plurality of inner ribs 25 protrude from the inner surface 214 of the ceiling wall 21 (see FIGS. 5 and 6). The plurality of inner ribs 25 each have a shape of a plate.

The fastening portions 23 and 23A are made of a resin, have a bottomed tubular shape, and are open on the ceiling wall 21 side. In addition, fixing through holes 231 that are used when attaching the housing 50 to the mount target are formed in the bottoms of the fastening portions 23 and 23A (see FIGS. 4 to 6). The housing 50 (the electrical junction box 100) can be attached to the mount target by inserting bolts 300 into the fixing through holes 231 of the fastening portions 23 and 23A from the mount target and threading the bolts 300 into nuts (not illustrated) provided in the fastening portions 23 and 23A.

Note that, as described above, inside the recessed portion 32a and the recessed portions 32b of the lower case 30, the fastening portions 23 of the upper case 20 are respectively disposed.

Various connection portions 212 for connection to another apparatus are provided at a plurality of locations of an outer surface 211 on the opposite side to the inner surface 214 of the ceiling wall 21. In addition, a plurality of mount seats 213 for relays 400 are provided in a substantially central portion of the outer surface 211 of the ceiling wall 21, and a plurality of relays 400 are mounted thereto. For convenience, FIG. 3 does not illustrate the relays 400.

Moreover, a plurality of outer ribs 24 protrude from the outer surface 211 of the ceiling wall 21. The outer ribs 24 include first outer ribs 24a for preventing warping caused by gravity and second outer ribs 24b for preventing warping caused by a difference in thermal expansion (see FIG. 3).

The first outer ribs 24a have a shape of a triangular plate, and are provided mainly in peripheral edge portions of the ceiling wall 21. That is to say, the length in the up-down direction of each of the first outer ribs 24a decreases toward the peripheral edge from a central portion of the ceiling wall 21. As described above, the first outer ribs 24a suppress the occurrence of warping of the ceiling wall 21 due to the weight of the relays 400 (see FIGS. 1 and 2) mounted in the central portion.

The second outer ribs 24b have a shape of a plate, and are provided in an end portion in the lengthwise direction of the ceiling wall 21. For convenience, in the present embodiment, a case will be described in which, as an example, the second outer ribs 24b are provided only in one end portion of the ceiling wall 21, but there is no limitation thereto, and the second outer ribs 24b may be provided in two end portions.

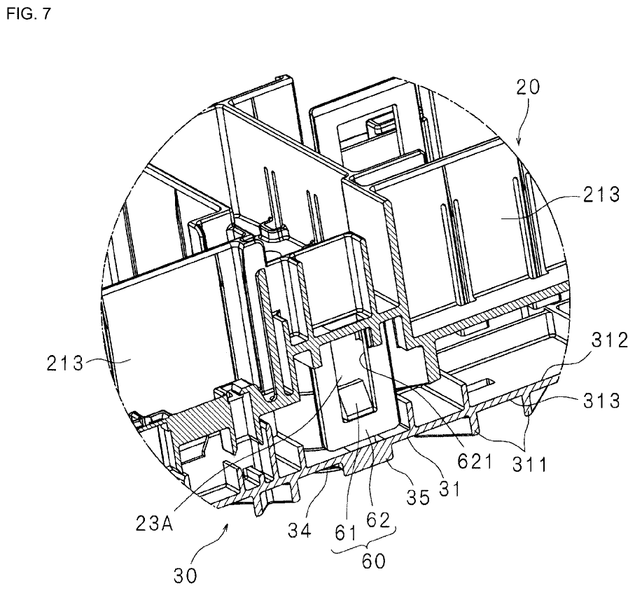

FIG. 5 is a partial cross-sectional perspective view taken along the line A-A in FIG. 4, FIG. 6 is a longitudinal cross-sectional view taken along the line A-A in FIG. 4, and FIG. 7 is a partial cross-sectional perspective view taken long the line B-B in FIG. 4. For convenience of description, in FIG. 6, the mount target (the battery pack 200) and the bolt 300 are indicated by phantom lines (one-dot chain lines).

As described above, a lower end portion of the fastening portion 23A in the substantially central portion of the ceiling wall 21 is inserted into the through tube 34 in the substantially central portion of the bottom wall 31. In addition, the lower end of the fastening portion 23A extends slightly beyond the lower end of the through tube 34, and the lower end surface of the fastening portion 23A is exposed to the outside.

A collar 40 is fitted into the fixing through hole 231 formed in the bottom of the fastening portion 23A. The collar 40 is made of metal, and has a shape of a ring. The collar 40 intervenes between the bolt 300 and the fastening portion 23A (the fixing through hole 231), and prevents collapse of the fastening portion 23A made of a resin due to threading of the bolt 300 made of metal. On the lower end surface of the fastening portion 23A, a rib having a shape of a recessed portion is disposed around the fixing through hole 231 (see FIG. 5).

In the electrical junction box 100 according to the present embodiment, a flexure preventing mechanism 60 for preventing flexure of the bottom wall 31 (central portion) is provided in the vicinity of the fastening portion 23A and the through tube 34. The flexure preventing mechanism 60 is disposed in a central portion of the bottom wall 31, and includes an engaging portion 61 provided on the lower case 30, and an engaged portion 62 that is provided in the upper case 20 and is engaged with the engaging portion 61.

The engaging portion 61 has a right-angled triangular shape in a longitudinal sectional view (see FIGS. 5 and 6), and is provided at one location of the upper end edge of the through tube 34. That is to say, the engaging portion 61 is formed integrally with the through tube 34. The engaging portion 61 extends upward from the upper end edge of the through tube 34, and protrudes beyond the outer peripheral surface of the through tube 34. Specifically, the length of the engaging portion 61 in the radial direction of the through tube 34 (hereinafter, referred to as a “thickness”) is larger than the thickness of the through tube 34, and decreases toward the upper end of the through tube 34.

The engaged portion 62 protrudes downward from the inner surface 214 of the ceiling wall 21, and is provided outward of the engaging portion 61 so as to correspond to the engaging portion 61 in the radial direction of the through tube 34 after attachment. That is to say, the engaged portion 62 is spaced apart from the outer peripheral surface of the fastening portion 23A with a predetermined distance therebetween, and is formed integrally with the fastening portion 23A via the ceiling wall 21. The distance between the engaged portion 62 and the fastening portion 23A is larger than the thickness of the through tube 34, and is smaller than the maximum thickness of the engaging portion 61.

In addition, the engaged portion 62 has a shape of a rectangular plate, and has a notch 621 formed therein and having a rectangular strip shape extending downward from the upper edge of the engaged portion 62. That is to say, the engaged portion 62 has a U-shape (see FIG. 7). The engaging portion 61 is inserted into the notch 621, and thus the engaging portion 61 and the engaged portion 62 are engaged with each other.

A check window 35 for checking whether or not the engaging portion 61 and the engaged portion 62 are engaged with each other as appropriate is formed in the vicinity of the through tube 34 in the bottom wall 31. The check window 35 is substantially rectangular, and passes through the bottom wall 31 in the thickness direction thereof. The edge of the check window 35 protrudes downward beyond the outer surface 313 of the bottom wall 31.

As described above, the electrical junction box 100 is attached to the outer side of a mount target such as the battery pack 200 from the bottom wall 31 side. Specifically, the bolts 300 are inserted into the fixing through holes 231 of the fastening portions 23 and 23A from the battery pack 200, and are threaded into the fixing through holes 231. At this time, there is a need to suppress loosening of threaded connection by abutting the collar 40 of the fastening portion 23A and the battery pack 200, which are made of metal and have small amounts of thermal expansion, on with each other.

However, when the central portion of the bottom wall 31 flexes downward, for example, due to the weight of the lower case 30 (see the arrow in FIG. 6), the bottom wall 31 or the through tube 34 and the ribs 311 come into contact with the battery pack 200 before the collar 40, and thus, in an operation of threading between the battery pack 200 and the fastening portion 23A, a problem occurs in that the collar 40 and the battery pack 200 are prevented from abutting on each other.

In contrast, in the electrical junction box 100 according to the present embodiment, the flexure preventing mechanism 60 is provided in the vicinity of the fastening portion 23A and the through tube 34, and thus, for example, it is possible to prevent the central portion of the bottom wall 31 from flexing downward due to the weight of the lower case 30. Thus, it is possible to prevent, in advance, the occurrent of the above problem of the collar 40 of the fastening portion 23A and the mount target (the battery pack 200) not abutting on each other due to flexure of the bottom wall 31.

In addition, in the electrical junction box 100 according to the present embodiment, as described above, the engaging portion 61 is formed integrally with the through tube 34, and the engaged portion 62 is formed integrally with the fastening portion 23A. Thus, when the upper case 20 and the lower case 30 are attached to each other, only by an operation of inserting the fastening portion 23A into the through tube 34, the engaging portion 61 and the engaged portion 62 are engaged with each other. Therefore, it is possible to increase the ease of assembly.

Furthermore, in the electrical junction box 100 according to the present embodiment, as described above, the check window 35 is formed in the vicinity of the through tube 34, and thus, when the upper case 20 and the lower case 30 are attached to each other, it is possible to check whether or not the engaging portion 61 and the engaged portion 62 are appropriately engaged with each other, via the check window 35.

The above describes a case where there is one flexure preventing mechanism 60 as an example, but there is no limitation thereto. Flexure preventing mechanisms 60 may be disposed at a plurality of locations in the central portion of the bottom wall 31.

In addition, a case has been described above in which, as an example, the engaging portion 61 is formed integrally with the through tube 34, and the engaged portion 62 is formed integrally with the fastening portion 23A, but there is no limitation thereto. A configuration may also be adopted in which the engaging portion 61 is formed integrally with the fastening portion 23A (the upper case 20), and the engaged portion 62 is formed integrally with the through tube 34 (the lower case 30).

The embodiment disclosed herein is exemplary in all respects and should not be interpreted as limiting in any manner. The scope of the present disclosure is defined not by the foregoing meanings, but is defined by the claims, and is intended to include all modifications that are within the meanings and the scope that are equivalent to those of the claims.

Matters described in the embodiment can be combined with each other. In addition, the independent claim and dependent claims described in CLAIMS can be combined with each other in any combination regardless of a reference format. Furthermore, a format in which a claim that refers to other two or more claims is written (multi claim format) is adopted for CLAIMS, but there is no limitation thereto. Claims may be written in a format in which a multi claim that refers to at least one multi claim (multi-multi claim) is written.

1. An electrical junction box that includes a mount portion to be used for mounting the electrical junction box to a target object, and is to be mounted, from one surface thereof, to the target object,
wherein the mount portion is positioned in a central portion of the one surface, and
a flexure preventing mechanism for preventing flexure of the one surface is provided in the vicinity of the mount portion.

2. The electrical junction box according to claim 1, further including:
a first case that includes the one surface and an open portion formed on an opposing side to the one surface; and
a second case that covers the open portion of the first case, and
the flexure preventing mechanism includes:
an engaging portion provided in the first case, and
an engaged portion that is provided in the second case and is engaged with the engaging portion.

3. The electrical junction box according to claim 2, further comprising
a check window that is formed in the one surface, and is for checking engagement between the engaging portion and the engaged portion.

4. The electrical junction box according to claim 2,
wherein the mount portion is provided on the second case, and is fitted into a through tube formed in the one surface,
the engaging portion is provided in the through tube, and
the engaged portion is formed integrally with the mount portion.

5. The electrical junction box according to claim 3,
wherein the mount portion is provided on the second case, and is fitted into a through tube formed in the one surface,
the engaging portion is provided in the through tube, and
the engaged portion is formed integrally with the mount portion.
